(19) United States
(12) Patent Application Publication
(10) Pub. No.: US 2025/0076439 A1
(43) Pub. Date: Mar. 6, 2025

(54) Echo-Planar Recording Technique that is Segmented in the Readout Direction for Creating Measurement Data by Means of Magnetic Resonance

(71) Applicant: Siemens Healthineers AG, Forchheim (DE)

(72) Inventor: Mario Zeller, Erlangen (DE)

(73) Assignee: Siemens Healthineers AG, Forchheim (DE)

(21) Appl. No.: 18/820,396

(22) Filed: Aug. 30, 2024

(30) Foreign Application Priority Data
Aug. 31, 2023 (DE) 10 2023 208 390.6

(51) Int. Cl. G01R 33/561; G01R 33/54; G01R 33/56

(52) U.S. Cl. CPC G01R 33/5616; G01R 33/543; G01R 33/5608; G01R 33/5611

(57) ABSTRACT

In a method for recording measurement data of an examination object, by a MR system using an echo planar recording technique that is segmented into at least two segments in the readout direction that also records navigator data (ND) for each of its segments, sampling patterns are changed during recordings of ND, so that the ND can be recorded overall such that reference data for determining further information for improving the recorded measurement data can be generated from the ND. The navigator phases of the recording technique segmented in the readout direction may be used to determine further information. The sampling patterns can be changed depending on the type of desired information and associated reference data. Separate measurements for reference measurements that are otherwise necessary for determining the desired information can be omitted, whereby a time period that is required for the entire measurement can be reduced.

### CROSS REFERENCE TO RELATED APPLICATIONS

This patent application claims priority to German Patent Application No. 10 2023 208 390.6, filed Aug. 31, 2023, which is incorporated herein by reference in its entirety.

### BACKGROUND

### Field

The disclosure relates to an improved echo planar recording technique that is segmented in the readout direction for creating measurement data by means of magnetic resonance.

### Related Art

The magnetic resonance technique (hereinafter the abbreviation MR stands for magnetic resonance) is a known technique with which it is possible to generate images of the interior of an examination object. In simple terms, the examination object is positioned in a magnetic resonance device in a comparatively strong static, homogeneous basic magnetic field, also called Bo field, with field strengths of 0.2 Tesla to 7 Tesla and more, so that its nuclear spins are oriented along the basic magnetic field. In order to trigger nuclear magnetic resonances that can be measured as signals, high-frequency excitation pulses (RF pulses) are irradiated into the examination object, the triggered nuclear magnetic resonances are measured as so-called k-space data and, on the basis of these, MR images are reconstructed or spectroscopy data is determined. For the local coding of the measurement data, rapidly switched magnetic gradient fields, called gradients for short, are superimposed on the basic magnetic field. A scheme used that describes a chronological sequence of RF pulses to be irradiated and gradients to be switched is referred to as a pulse sequence (scheme), or also abbreviated as a sequence. The measurement data that is registered is digitized and stored as complex numerical values in a k-space matrix. An associated MR image can be reconstructed from the k-space matrix that is allocated values, for example by means of a multidimensional Fourier transformation.

In recent years, an acceleration of MR measurements by targeted sub-sampling of the k-space, for example by so-called parallel recording techniques, has been established. The aforementioned parallel recording techniques (ppa techniques), with the help of which acquisition times that are required to record the desired data can be shortened by a sampling that is not complete in accordance with Nyquist, i.e. a sub-sampling of the (2D) k-space, include, for example, GRAPPA (“GeneRalized Autocalibrating Partially Parallel Acquisition”) and SENSE (“SENSitivity Encoding”). In the case of parallel recording techniques, the measurement points in the k-space that are not measured within the scope of the sub-sampling are generally distributed uniformly over the k-space to be measured in accordance with Nyquist, so that, for example, every second k-space line is measured in each k-space plane (kx, ky) that is allocated to a layer. Such PPA techniques are therefore also referred to as “in-plane” acceleration techniques.

The “missing” k-space data is reconstructed with the help of coil sensitivity data in parallel recording techniques. This coil sensitivity data of the receiving coils that are used in the recording of the measurement data are determined from reference measurement data that completely samples at least one region of the k-space to be measured, usually the central region, in accordance with the Nyquist condition. The coil sensitivity data that is determined from the reference measurement data for a reconstruction of missing k-space data is also referred to as a “kernel,” in the case of GRAPPA also as a “GRAPPA kernel.”

Any measurement data from which image data is not (or not only) reconstructed, but which is used as a reference for determining further information for a technique or algorithm that is used, is referred to herein as reference measurement data. Such reference measurement data must generally be recorded in addition to measurement data that is recorded for imaging, which increases the overall time that is required for such measurements.

In some examinations, it is necessary to perform multiple, i.e. a whole series of recordings of measurement data of the examination object, wherein a certain measurement parameter is varied. On the basis of the measurements, the effect of this measurement parameter on the examination object is observed in order to draw diagnostic conclusions from it later. A series is to be understood as at least two, but usually more than two recordings of measurement data sets. In this case, a measurement parameter is expediently varied in such a manner that the contrast of a certain material type that is excited during the measurements, for example a tissue type of the examination object or a chemical substance that is significant for most or certain tissue types, such as water, is influenced as strongly as possible by the variation of the measurement parameter. This ensures that the effect of the measurement parameter on the examination object is particularly visible.

A typical example for series of magnetic resonance recordings under the variation of a measurement parameter that strongly influences the contrast are so-called diffusion weighting imaging (DWI) methods. Diffusion is the Brownian motion of molecules in a medium. In diffusion imaging, as a rule, multiple images with different diffusion directions and weights are recorded and combined with one another. The strength of the diffusion weighting is usually defined by the so-called “b value.” The diffusion images with different diffusion directions and weightings or the images combined therefrom can then be used for diagnostic purposes. Thus, parameter maps with special diagnostic significance can be generated by suitable combinations of the recorded diffusion-weighted images, such as maps that reproduce the “Apparent Diffusion Coefficient (ADC)” or the “Fractional Anisotropy (FA).”

In diffusion-weighted imaging, additional gradients that reflect a respective diffusion direction and a respective diffusion weighting are inserted into a pulse sequence in order to make the diffusion properties of the tissue visible or to measure them. These gradients lead to tissue with rapid diffusion (for example, “cerebral spinal fluid” CSF) being subject to a greater signal loss than tissue with slow diffusion (for example, the grey matter in the brain). The resulting diffusion contrast is becoming clinically increasingly important and applications now go far beyond the classic early detection of ischemic stroke.

Due to the short acquisition time of per image and its robustness to movement, diffusion imaging is often based on EPI recording techniques described below, in particular on RESOLVE (Readout SEgmentation Of Long Variable Echo-trains) techniques that are extended by diffusion preparation.

Such EPI recording techniques (EPI: Echo planar imaging) are among the fastest known MR recording techniques. In EPI recording techniques, an oscillating, i.e. bipolar readout gradient is used after an RF excitation pulse, which refocuses the transverse magnetization as far as the T2*decay allows with each change in the polarization direction of the gradient, and thus generates one gradient echo each. In other words, by switching the bipolar readout gradient after an RF excitation pulse within the free induction drop after the excitation (fid), or if an RF refocusing pulse is additionally irradiated after the RF excitation pulse, an echo train of rising and falling gradient echoes with changing signs is generated within the spin echo that is thus generated. EPI pulse sequences can be used as a so-called “single-shot” method, in which all measurement data for generating an image of a subvolume, for example a layer, of the examined examination object are recorded after only one RF excitation pulse.

It is also possible to record the k-space in segments, i.e. to record measurement data in a segmented manner. In principle, the segmentation of the k-space can take place in the phase coding direction and/or in the readout direction.

The RESOLVE recording technique described for the first time in the article by Porter and Heidemann “High Resolution Diffusion-Weighted Imaging Using Readout-Segmented Echo-Planar Imaging, Parallel Imaging and a Two-Dimensional Navigator-Based Reacquisition,” MRM 62, 2009, p. 468-475, is a variant of an EPI recording technique in which segmentation takes place in the readout direction instead of in the phase coding direction.

In general terms, in the case of a RESOLVE sequence, for example after a diffusion preparation, the segment of the k-space that is to be filled with measurement data in the following readout phase is defined by a prephasing gradient. In the readout phase, a train of echo signals is recorded as measurement data for the defined segment by means of a sinusoidal readout gradient. By means of a further gradient, which has an opposite polarity to the prephasing gradient and is switched after the readout phase, the system returns to the k-space center in the readout direction before a further refocusing pulse is irradiated, which leads to the formation of further echo signals, which are recorded as navigator data of the k-space center by means of a navigator readout gradient. The navigator data thus recorded for each segment is used to allow a non-linear phase correction of possible phase changes between the recordings of the measurement data in the individual segments and to detect segments whose measurement data are unusable and are to be repeated, as described in more detail in the article by Porter and Heidemann already mentioned above. Measurement data that is recorded by means of RESOLVE can also be recorded in an accelerated manner in the phase coding direction, for example in accordance with a parallel recording technique, i.e. measurement data is not recorded in the phase coding direction along all the k-space lines that are provided for a complete sampling of the k-space in accordance with Nyquist, but, depending on the acceleration factor PAT=n, only along every nth k-space line.

FIG. 1 shows a schematic illustration of a part of a RESOLVE pulse sequence scheme 11 that illustrates the gradient to be switched and RF pulses to be irradiated in their chronological sequence.

A diffusion preparation block comprises an RF excitation pulse 12, during the irradiation of which a layer selection gradient 14 is switched in the layer selection direction G_{S}, and an RF refocusing pulse 13, during the irradiation of which a layer selection gradient 15 is switched. The layer selection gradients are used to select a layer in an examination object in which echo signals are to be excited and read out as measurement data. In addition, a rephasing gradient 16 can be switched in the layer selection direction in order to compensate for possible dephasing of the excited spins by the layer selection gradient 14. Diffusion gradients 17, 18, 19 and 20, 21, 22 of the diffusion preparation block are switched in the usual manner chronologically before and after the RF refocusing pulse 13.

The RF excitation pulse 12 and the associated layer selection gradient 14 and rephasing gradient 16 can be associated with an excitation phase 23 of the pulse sequence scheme that is followed by an evolution phase 24 that continues until the completion of the diffusion gradients 20, 21, 22.

The diffusion preparation block is followed by a readout phase 25, which comprises a prephasing gradient 26 in the readout direction G_{R}. The prephasing gradient 26 defines the segment of the k-space that is to be filled with measurement data in the following readout time window, since it specifies the start coordinate of the readout trajectory in the k-space in the readout direction. By varying the moment of the prephasing gradient 26 in various repetitions of the pulse sequence, the various segments can be read out in the readout direction G_{R}, as is illustrated, for example, in FIG. 2.

The prephasing gradient 26 is followed in the readout direction G_{R} by a sinusoidal readout gradient 27, which comprises a plurality of arcs 30, 31, 32, 33, 34, 35, 36, 37. Each of the arcs 30-37 encodes a distance along the readout direction GR in the k-space.

Phase encoding gradients 38 switched in the phase encoding direction G_{P}, also referred to as “blips,” shift the encoding step by step in the phase encoding direction, so that an EPI-typical readout trajectory is obtained by the readout gradient 27 and the phase encoding gradients 38 in segments.

A first phase encoding gradient 39 of the readout phase 25, similar to the prephasing gradient 26 in the readout direction, defines the start coordinate of the readout trajectory in the k-space in the phase encoding direction.

In the readout phase 25, the generated echo signals 40, such as all echo signals 40 belonging to a segment, are detected in a readout window. The echo signals 40, which are excited by an excitation phase 23, form an echo train 41. After the last echo 40 of the echo train 41 has been detected at the end of the readout phase 25, the coding can be returned to the k-space center in the readout direction by a further gradient 42, which has an opposite polarity to the prephasing gradient 26.

The readout phase 25 is followed by a navigator phase 43, in which gradients 44, 45, 39′ and 47 are switched, which operate analogously to the gradients that are switched in the readout phase, wherein only one segment is generally read out in the navigator phase. The echo signals 48 are generated after irradiation of an RF refocusing pulse 49 by switching a layer selection gradient 50.

FIG. 2 illustrates an example of a sampling scheme in the k-space that can be achieved with a RESOLVE pulse sequence scheme according to FIG. 1. In this case, the axis 51 shows the kx direction by way of example and the axis 53 the ky direction. Here, the kx direction corresponds to the readout direction and the ky direction corresponds to the phase encoding direction.

After a preparation of the spins, for example a diffusion preparation by means of diffusion gradients 17, 18, 19, 20, 21, 22, a first starting point 54 for sampling a segment 63 can be defined by the gradients 26 and 39. The partial k-space line 55 is detected while the arc 30 of the readout gradient 27 is switched. The partial k space line 56 is detected while the arc 31 of the readout gradient 27 is switched. The shifting in the phase encoding direction between the partial k space lines 55 and 56 is achieved by switching a blip 38.

The further partial k space lines 57, 58, 59, 60, 61 and 62 are detected analogously during switching of the arcs 32, 33, 34, 35, 36 and 37. The partial k-space lines 55 to 62 each correspond to an echo signal 40 and form an echo train 41.

The partial k space lines 55 to 62 cover the segment 63 of the k-space 52 that is segmented in the readout direction as an example into the segments 62 to 67.

If the pulse sequence scheme 11 is applied with a dephasing gradient 26 with a different gradient moment, echo signals of another of the segments 64, 65, 66 or 67 of the k-space 52 can be detected. In this case, the (zero) moment of a switched prephasing gradient 26 should correspond to a multiple (corresponding to the arrangement of the segment) of the (zero) moment (only the term “moment” is used below) of an arc 32-37 of the readout gradient 27, since a discrepancy between the moments of the prephasing gradient 26 and an arc 30-37 of the readout gradient 27 leads to so-called ringing artifacts when the echo signals 40 that are detected in the individual segments as measurement data are combined.

If an echo train 41 comprises all echo signals 40 that are to be detected for a segment 63 to 67, in total as many excitation cycles are switched as segments are provided in order to detect all echo signals 40 of all segments 63 to 67.

If an echo train 41 detects only a part of the echo signals 40 that are to be detected for a segment 63 to 67, correspondingly more excitation cycles must be switched. In this case, the k-space can also be referred to as segmented in the phase encoding direction.

In the illustrated example, the trajectories 68 and 69 (in the segments 63 and 64) are illustrated at a certain distance in the readout direction. This is only for better presentation. In fact, echo signals can be detected in such a manner that overall no gaps arise in the detected k-space in the readout direction, so that segmented, but overall complete k-space lines can be sampled in the readout direction. The partial k-space lines that are contained in the exemplary marked fields 70 and 85 then supplement each other to form a complete k-space line.

Due to the changing polarity of the readout gradient, in all EPI recording techniques, the measurement data that is obtained from the gradient echo signals must be sorted into a raw data k-space matrix in such a manner that the sorting direction changes from line to line of the raw data k-space matrix. If there are even only slight deviations from line to line, for example due to delays in the gradient circuit or eddy currents, without correction this leads to so-called N/2 ghosts, i.e. in the case of an image matrix of N×N points, the actual image is displayed again shifted by N/2 in the positive and negative direction with respect to the image matrix center, and namely generally with different intensity. For the correction of such N/2 ghosts, it is known, for example, from U.S. Pat. No. 6,043,651, to record three navigator signals by switching a bipolar readout gradient, with which a correction of phase shifts of zero and first order between gradient echoes that are recorded with different polarity can be performed in the readout direction, which can correct such shifts. For this purpose, a correlation of the recorded navigator signals in the image space is used to determine correction factors that are used in a reconstruction of image data from the gradient echoes that are recorded as measurement data in a raw data k-space matrix in order to correct the said shifts in the raw data k-space matrix.

A further phase correction method, called DORK, for correcting shifts caused by temporal variations of a basic magnetic field that is present during an EPI measurement, for example a drift, in which a navigator signal is recorded, is known, for example, from U.S. Pat. No. 9,329,254 B2. In this case, an evolution of the gradient echoes that were recorded with one polarity is compared with an evolution of the gradient echoes that were recorded with the other polarity via successive recordings of raw data k-space matrices. In the case of such a DORK correction, averaging is usually performed over a total image volume.

As a rule, it is possible with such known correction methods to reduce asymmetries in the measurement data measured for imaging, and, if these are also recorded by means of EPI, also in reference measurement data, to such an extent that the expression of residual ghosts in their image data (image ghosts) no longer plays a real role for clinical diagnostics.

However, such correction methods that operate on the basis of one-dimensional navigator signals can reach their limits, in particular if the interference fields that cause inconsistencies have spatial variations not only along the readout direction. In this case, an intensity of image ghosts is still reduced, but image artifacts possibly still remain, which can lead to limitations in clinical usability.

By means of a, for example in the article by Hoge et al, “Dual-Polarity GRAPPA for Simultaneous Reconstruction and Ghost Correction of Echo Planar Imaging Data,” Magn. Reason. Med. 76: P. 32-44, 2016, it is possible to reduce the intensity of image ghosts, even in the case of complex geometries of the interference fields, to such an extent that the images are suitable without restriction for clinical diagnosis.

For such a DPG approach, further reference measurement data is required. In particular, sets of reference measurement data that are completely recorded in accordance with Nyquist are used for each desired layer and both polarization directions, from which complete reference measurement data sets for each polarization direction are generated in each case, which are used to generate coil sensitivity data for both polarization directions, which are used in the reconstruction of image data from measurement data that is generally undersampled by means of an EPI recording technique in the context of the DPG method, in order to largely avoid ghost artifacts, in particular even under conditions with nonlinear phase variations. For example, prior to the implementation of the actual DPG algorithm for reference measurement data it is possible for a DPG algorithm to be combined from two sets of reference measurement data that is recorded with in each case inverted polarities of the readout gradients, a completely sampled set of sorted reference measurement data with only one readout direction in each case, that is to say only with positive polarity of the readout gradient in each case or only negative polarity of the readout gradient in each case, for example by corresponding allocation of recorded k-space lines.

In its original form, an algorithm that is used in the case of DPG simultaneously ensures the reduction of image ghosts and the addition of k-space data that is missing due to the GRAPPA technique that is used. Modified variants, however, can also only reduce the asymmetries of the measurement data that is recorded with positive or negative readout gradients in the k-space, so that a reduction of image ghosts is also possible for fully sampled measurement data for imaging, for example also imaging by means of an SMS technique, and/or for alternative reconstruction methods (for example, DL-based addition of missing k-space data).

In conventional methods for recording the reference measurement data for the application of a DPG algorithm, it is necessary to record two sets of reference measurement data with inverted polarity of the readout gradients.

For example, in a conventional method, reference measurement data for a DPG algorithm is record by means of a single-shot EPI recording technique, in which reference measurement data is recorded by means of an EPI recording technique for each layer in which measurement data for imaging is recorded, after in each case one excitation.

As another example, reference measurement data for DPG algorithms may be recorded by means of a multi-shot EPI recording technique, in which the reference measurement data of each layer for which measurement data for imaging is to be recorded is recorded with a plurality of excitations of a segmented EPI recording technique.

For the recording of reference measurement data for a DPG algorithm with a multi-shot EPI recording technique, a conventional segmentation can be used, in which the k-space to be recorded is divided into segments from which reference measurement data is recorded according to an excitation.

For the recording of reference measurement data for a DPG algorithm with a multi-shot EPI recording technique, a so-called fleet technique (FLEET: “fast low-angle excitation echo-planar technique”), as described, for example, in the article by Polimeni et al. “Reducing Sensitivity Losses Due to Respiration and Motion in Accelerated Echo Planar Imaging by Reordering the Autocalibration Data Acquisition,” Magn. Reson. Med. 75, p. 665-679, 2016, and in which the reference measurement data of the individual segments is recorded in a short temporal sequence. In this case, the flip angle of the respective excitation between the different segments is varied in order to ensure a similar contrast.

A recording of reference measurement data for a DPG algorithm takes a not inconsiderable amount of time in any case. If further reference measurement data, for example for a parallel recording technique, in particular for supplementing unsampled k-space data, is to be recorded, the overall time that is required for recording all reference measurement data is further increased. In addition, between recordings of different reference measurement data, it is often necessary to use further time-consuming so-called dummy recordings during which no data is recorded, in order for example to compensate for steady-state effects.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a schematic illustration of a RESOLVE pulse sequence scheme according to the disclosure.

FIG. 2 shows an example of a sampling scheme in the k-space that can be achieved with a RESOLVE pulse sequence scheme according to the disclosure.

FIG. 3 is a flowchart of a method according to the disclosure.

FIG. 4 shows schematic exemplary sampling schemes for recording navigator data in according to the disclosure.

FIG. 5 shows schematic representations of parts of RESOLVE pulse sequence schemes, according to the disclosure, with which the sampling patterns of FIG. 4 can be achieved.

FIG. 6 shows a schematically illustrated magnetic resonance system according to the disclosure.

The exemplary embodiments of the present disclosure will be described with reference to the accompanying drawings. Elements, features and components that are identical, functionally identical and have the same effect are-insofar as is not stated otherwise-respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to enable a RESOLVE recording technique with a shortened recording of required or desired reference measurement data and thus shortened overall measurement times compared to the known methods.

The object is achieved by a method for recording measurement data of an examination object by means of a magnetic resonance system using an echo planar recording technique that is segmented into at least two segments in the readout direction, in particular a RESOLVE recording technique that also records navigator data for each of its segments.

A method in accordance with the disclosure for recording measurement data of an examination object may include the following operations. The method may be performed using a magnetic resonance system using an echo planar recording technique that is segmented into at least two segments in the readout direction, in particular a RESOLVE recording technique that also records navigator data for each of its segments. According to the disclosure, the method may include:
recording the measurement data and associated navigator data in each of the at least two segments after a common RF excitation pulse (12) in accordance with the echo planar recording technique that is used, which is segmented in the readout direction, for all of the at least two segments, wherein a sampling pattern, in accordance with which navigator data is recorded, is changed in at least one of the recordings of measurement data of the at least two segments with their associated navigator data,
generating reference data to determine further information so as to improve the recorded measurement data from navigator data that includes the navigator data that was recorded with a changed sampling pattern, and
improving the recorded measurement data on the basis of the generated reference data.

By means of sampling patterns that are changed in accordance with the disclosure during various recordings of navigator data, the navigator data can be recorded overall in such a manner that reference data for determining further information for improving the recorded measurement data can be generated from said navigator data. The navigator phases, which are to be performed anyway, of the echo planar recording technique that is segmented in the readout direction are thus used efficiently in order to be able to determine further information. The sampling patterns can be changed accordingly depending on the type of desired information and associated reference data. In this manner, separate measurements for reference measurements that are otherwise necessary for determining the desired information can be omitted, whereby a time period that is required for the entire measurement with all reference measurements can be reduced.

A magnetic resonance system in accordance with the disclosure may comprise a magnetic unit, a gradient unit, a high-frequency unit and a controller (control facility) having a reference measurement data unit that is adapted to implement a method in accordance with the disclosure.

A computer program in accordance with the disclosure implements a method in accordance with the disclosure on a controller when it is executed on the controller. For example, the computer program comprises commands that, when the program is being executed by a controller, for example a controller of a magnetic resonance system, prompt this controller to execute a method in accordance with the disclosure. The controller can be designed in the form of a computer.

In this case, the computer program can also be in the form of a computer program product, which can be loaded directly into a memory of a controller, having program code means in order to implement a method in accordance with the disclosure if the computer program product is executed in a computer (computer unit, processer) of the computer system.

A computer readable storage medium in accordance with the disclosure comprises commands that, when the program is being executed by a controller, for example a controller of a magnetic resonance system, prompt this controller to execute a method in accordance with the disclosure.

The computer-readable storage medium can be designed as an electronically readable data carrier, which comprises electronically readable control information that is stored thereon, which comprises at least one computer program in accordance with the disclosure and is designed in such a manner that, when the data carrier is used in a controller of a magnetic resonance system, it implements a method in accordance with the disclosure.

The advantages and embodiments specified in relation to the method also apply analogously to the magnetic resonance system, the computer program product and the electronically readable data carrier.

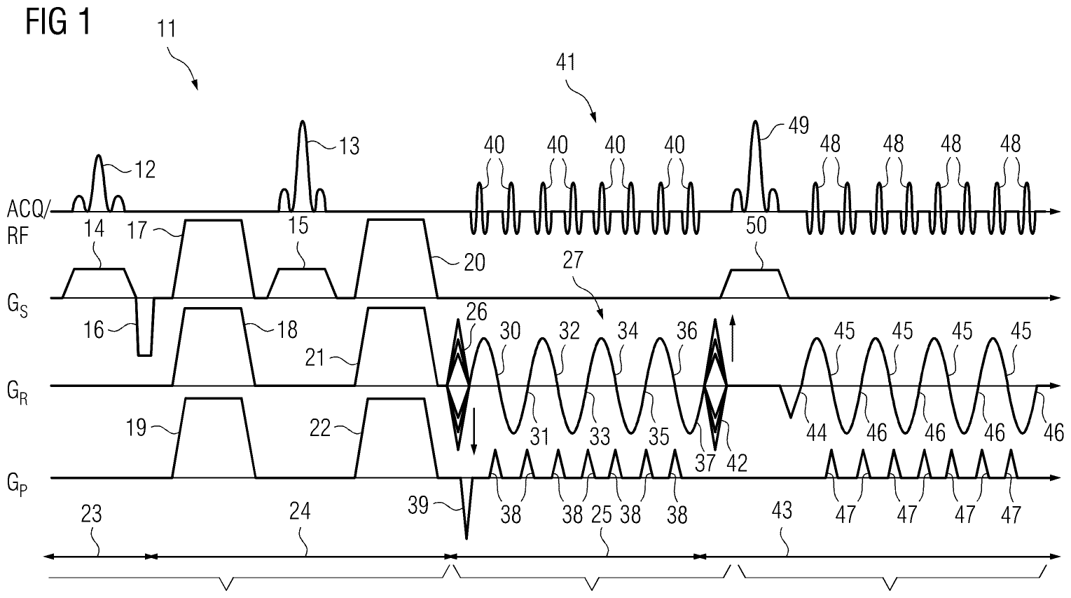

FIG. 1 is a schematic flowchart of a method in accordance with the disclosure for recording measurement data MD(Si) of an examination object by means of a magnetic resonance system using an echo planar recording technique that is segmented into at least two segments Si in the readout direction, in particular a RESOLVE recording technique that also records navigator data for each of its segments Si.

Measuring data MD(Si) is recorded in each of the at least two segments Si and associated navigator data Nav after a common RF excitation pulse in accordance with the echo planar recording technique that is used, which is segmented in the readout direction, for all of the at least two segments (block 301). In this case, a sampling pattern, in accordance with which navigator data is recorded, is changed in at least one of the recordings of measurement data of the at least two segments with their associated navigator data, so that the changed sampling pattern differs from a sampling pattern with which navigator data that is associated with measurement data of at least one other of the at least two segments Si was recorded (block 303).

In this case, navigator data can be recorded in each case in the segment Si of the echo planar recording technique, which is segmented into at least two segments Si in the readout direction and which comprises the k-space center (regardless of the segment Si in which the associated measurement data is recorded in the recording after the common RF excitation pulse). In this manner, the recorded navigator data has the greatest possible contrast.

The measurement data and the associated navigator data can be recorded after applying a diffusion preparation block, so that the method can be used for diffusion imaging. In this case, a change in sampling patterns in accordance with the disclosure can be restricted to recordings of measurement data and associated navigator data without diffusion coding (b=0), since possible phase errors occur primarily in the case of diffusion coding b>0.

In this case, when a sampling pattern is changed, an acceleration factor corresponding to the sampling pattern cannot be changed. Thus, an acceleration factor of a changed sampling pattern further corresponds to an acceleration factor of an unmodified sampling pattern. This ensures that an echo distance at which navigator data is recorded in accordance with a changed sampling pattern remains the same as an echo distance at which navigator data is recorded in accordance with an unchanged sampling pattern.

The sampling pattern can be changed in such a manner that the readout direction in which the navigator data is recorded reverses with the changed sampling pattern.

Additionally, or alternatively, the sampling pattern can be changed in such a manner that the positions in the phase encoding direction at which the navigator data is recorded shift with the changed sampling pattern, for example by one or a multiple of a step size that is provided in accordance with an echo planar recording technique that is segmented into at least two segments Si and used in the readout direction in the phase encoding direction during the sampling of the k-space.

FIG. 4 shows schematically illustrated exemplary sampling schemes as can be used in a method in accordance with the disclosure for recording navigator data. In this case, k-space lines along which navigator data is recorded are shown as arrows, which in each case point in the readout direction. For a complete sampling of the k-space in accordance with Nyquist, k-space lines that are provided but not read out in the shown example are shown as dotted lines.

The sampling scheme sh1 shown on the far left for a first recording of navigator data in one of the segments Si can be, for example, an unchanged sampling scheme. In the example shown, navigator data is recorded for every second k-space line under EPI-typical changes in the readout direction. Thus, an acceleration factor PAT=2 is present.

In the illustrated example, the same k-space lines as in the first recording sh1 are recorded with a sampling pattern sh2, which can be used, for example, in a second recording of navigator data, but with inverted readout directions. The sampling pattern sh2 was thus changed here only with regard to its readout directions with respect to the sampling pattern sh1.

With a sampling pattern sh3 shown in the illustrated example, which can be used, for example, in a third recording of navigator data, navigator data is recorded along the hitherto unread k-space lines, but with readout directions that correspond to those of the sampling pattern sh1. The sampling pattern sh3 was thus shifted here with respect to the sampling pattern sh1 only in the phase coding direction.

In the illustrated example, the same k-space lines as in the sampling pattern sh3 are recorded with a sampling pattern sh4, which can be used, for example, in a fourth recording of navigator data, but with inverted readout directions. The sampling pattern sh4 was thus changed here with regard to the sampling pattern sh1 both with regard to the readout directions that are used and also shifted in the phase encoding direction.

A further sampling pattern sh5, which can be used, for example, in a fifth recording to record navigator data, is shown on the far right. The sampling pattern sh completely samples the central k-space in accordance with Nyquist. The sampling pattern sh5 was thus also changed here with regard to the associated acceleration factor.

A typical RESOLVE sequence usually comprises at least five segments, sometimes also seven segments or even 9 segments. As a result, at least four to 8 recordings of navigator data can be made in accordance with a sampling pattern that is changed compared to the original sampling pattern, so that various reference data RD can be generated without additional recordings of reference measurement data being necessary, but rather such additional recordings can be omitted, as a result of which measurement time is saved.

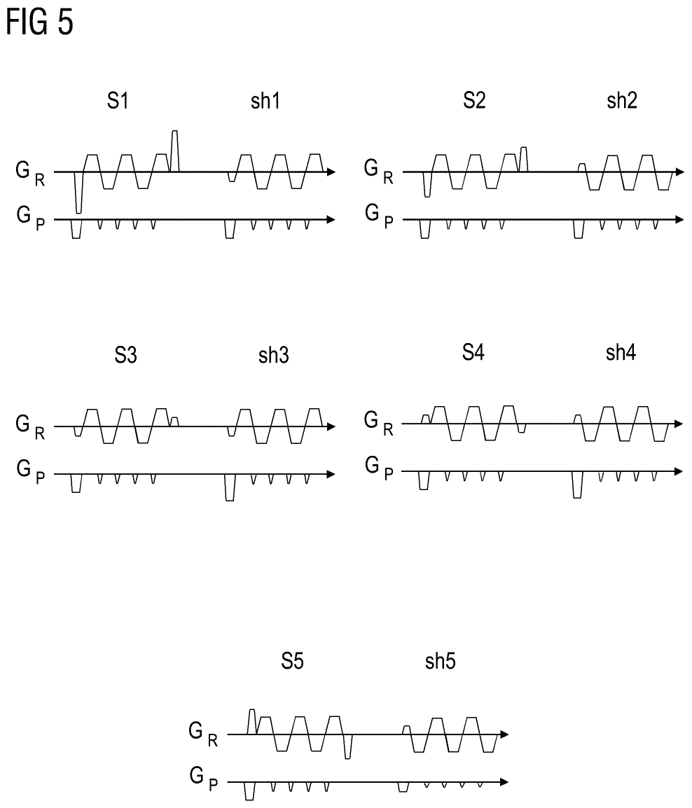

FIG. 5 shows schematic representations of parts of RESOLVE pulse sequence schemes with which the sampling patterns of FIG. 4 can be achieved. For clarity, only the gradients to be switched in the readout direction GR and in the phase encoding direction GR are illustrated because the differences from the pulse sequence scheme illustrated in FIG. 1 are represented.

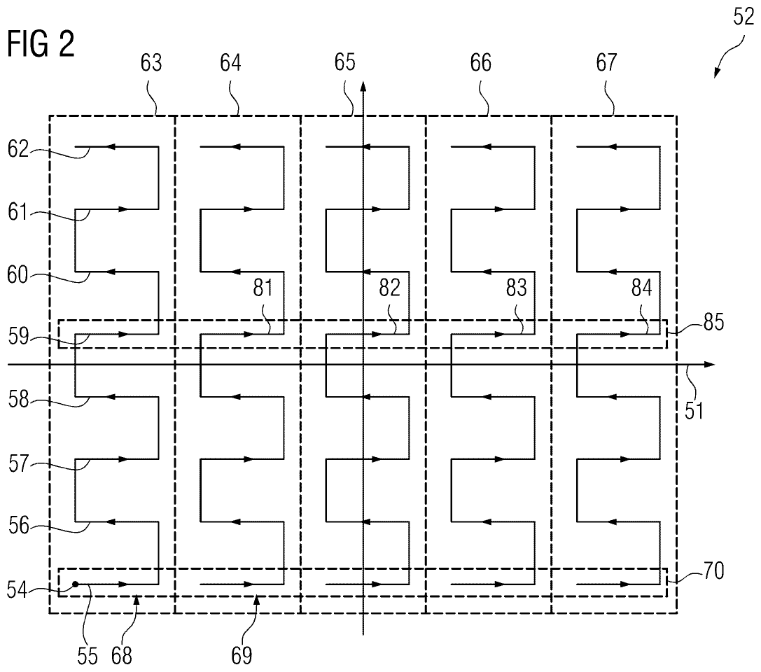

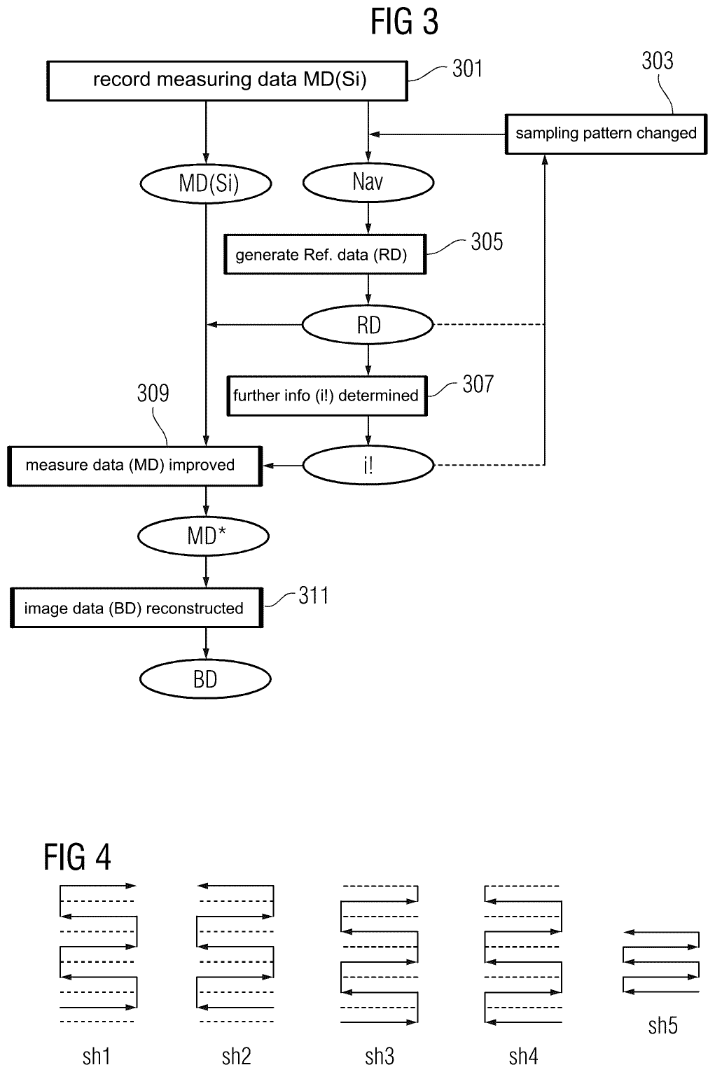

In further contrast to FIG. 1, the recordings of measurement data in a segment S1, S2, S3, S4, S5 with their associated different prephasing gradients, which can correspond, for example, to the segments 63 to 67 of FIG. 2, are shown here individually. A sampling scheme used for recording the measurement data remains the same for all segments S1 to S5, as can be seen from the always constant readout gradients according to the respective prephasing gradients. However, the sampling schemes sh1, sh2, sh3, sh4, sh5 for recording the navigator data are changed as described in FIG. 4, which is why the gradients that are switched in the readout direction and phase encoding direction in the respective navigator phase differ for each of the sampling patterns as illustrated.

From navigator data that includes the navigator data that was recorded with a changed sampling pattern, reference data RD is generated to determine further information i! to improve the recorded measurement data (block 305). The desired further information i! can be determined on the basis of the generated reference data RD (block 307).

The reference data RD can be used, for example, as a reference for determining information i! for a correction method, such as, for example, a correction of N/2 ghosts, in particular a DPG technique, and/or for a supplementing method for supplementing measurement data that is not recorded, such as, for example, a GRAPPA method.

If the reference data RD is to be used as a reference for a DPG technique, the sampling pattern in accordance with which navigator data is recorded, can be changed so often that due to the changed sampling patterns overall navigator data is recorded which completely samples the k-space for each readout direction in accordance with Nyquist. This is the case, for example, for the sampling patterns sh1, sh2, sh3 and sh4 of FIG. 4.

If the reference data RD is to be used as a reference for a supplementing method for supplementing measurement data that is not recorded, changed sampling patterns can be selected such that they together result in a combined sampling pattern or that a combined sampling pattern can be created from them that completely samples the k-space center in accordance with Nyquist. This is already the case, for example, for a sampling pattern combined from one of the sampling patterns sh1 or sh2 with one of the sampling patterns sh3 or sh4, wherein different readout directions are present here for different parts of the combined sampling pattern. As already mentioned above, a separate complete set of navigator data in accordance with Nyquist can even be combined from the four sampling patterns sh1, sh2, sh3 and sh4 for each readout direction. One advantage of such combined sampling patterns is that an echo distance that is used in the recording of the navigator data corresponds to the echo distance of the recording of the measurement data.

If the reference data RD is used as a reference for a supplementing method for supplementing measurement data that is not recorded, the changed sampling pattern can be selected corresponding to a sampling pattern that is used for recording reference measurement data for a parallel acceleration technique, for example in-plane GRAPPA, which completely samples the k-space center in accordance with Nyquist. This is the case, for example, for the sampling pattern sh5 of FIG. 4.

The recorded measurement data MD is improved on the basis of the generated reference data RD (block 309), whereby improved measurement data MD* is obtained from which image data BD can be reconstructed (block 311), which can have a higher quality due to the improvement of the measurement data.

If navigator data is recorded at least once in accordance with an unchanged sampling pattern, a conventional non-linear phase correction can be performed on the basis of this navigator data. Reference data RD that has been generated from navigator data that is generated in accordance with a sampling pattern that completely samples the k-space center in accordance with Nyquist can also be used in such a phase correction in order to supplement navigator data that is not recorded and to reconstruct image data that can be subjected to a phase correction method from the supplemented navigator data. The phase-corrected image data can be transformed back into the frequency space (k-space) in order to obtain corrected k-space data, from which in turn improved reference data RD can be generated.

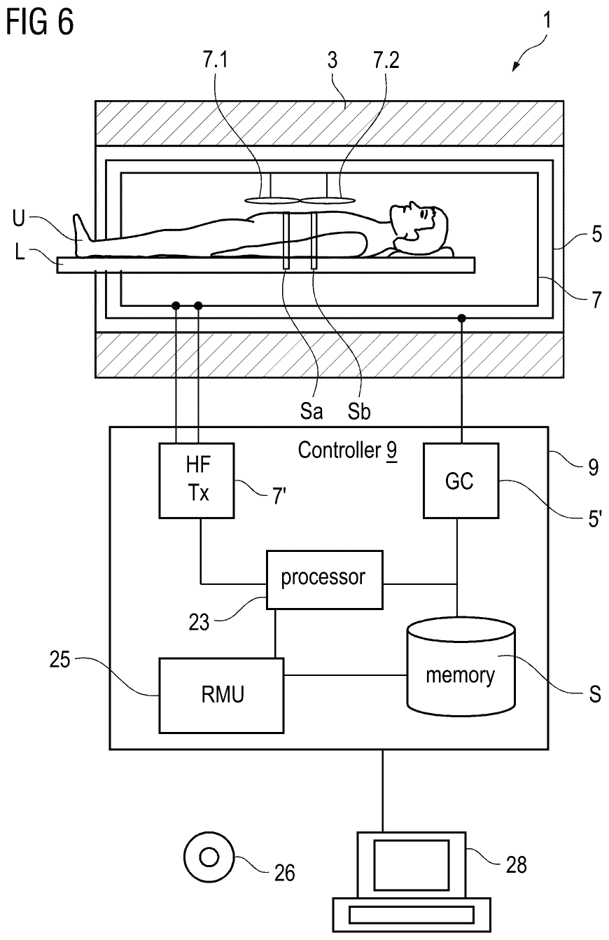

FIG. 6 schematically illustrates a magnetic resonance system 1 in accordance with the disclosure. This comprises a magnetic unit 3 for generating the basic magnetic field, a gradient unit 5 for generating the gradient fields, a high-frequency unit 7 for irradiating and for receiving high-frequency signals and a controller 9 that is adapted to implement a method in accordance with the disclosure. The magnetic unit 3, gradient unit 5, and high-frequency unit 7 may collectively be referred to as a magnetic resonance scanner. In an exemplary embodiment, the controller 9 includes processing circuitry that is adapted to perform one or more functions and/or operations of the controller 9. Additionally, or alternatively, one or more components of the controller 9 may include processing circuitry that is adapted to perform the function(s) and/or operation(s) of the respective component(s).

In FIG. 6, these sub-units of the magnetic resonance system 1 are schematically illustrated. In particular, the high-frequency unit 7 can comprise a plurality of subunits, for example a plurality of coils such as the schematically illustrated coils 7.1 and 7.2 or more coils, which can be configured either only for transmitting high-frequency signals or only for receiving the triggered high-frequency signals or for both.

In order to examine an examination object U, for example a patient or even a phantom, it can be introduced into the magnetic resonance system 1 in its measurement volume on a couch L. The layers Sₐ and S_{b} represent exemplary target volumes of the examination object from which echo signals are to be recorded and captured as measurement data.

The controller 9 may be adapted to control the magnetic resonance system 1 and may control the gradient unit 5 by means of a gradient controller 5′ and the high-frequency unit 7 by means of a high-frequency transceiver controller 7′. In this case, the high-frequency unit 7 can comprise a plurality of channels on which signals can be transmitted or received.

Together with its high-frequency transceiver controller 7′, the high-frequency unit 7 is responsible for generating and irradiating (transmitting) a high-frequency alternating field for manipulating the spins in an area to be manipulated (for example in layers Sa, Sb to be measured) of the examination object U. In this case, the center frequency of the high-frequency alternating field, also referred to as the B1 field, is generally set as close as possible to the resonant frequency of the spins to be manipulated. Deviations from the center frequency from the resonant frequency are referred to as off-resonance. In order to generate the B1 field, controlled currents are applied to the HF coils in the high-frequency unit 7 by means of the high-frequency transceiver controller 7′.

In addition, the controller 9 comprises a reference measurement data unit 25, with which it is possible to control a recording of reference measurement data in accordance with the disclosure. Overall, the controller 9 is designed so as to implement a method in accordance with the disclosure.

A computing unit (computer, processor) 23 that the controller 9 comprises is designed to perform all the computing operations that are required for the necessary measurements and determinations. Intermediate results and results required for this or determined in this case can be stored in a storage unit (memory) S of the controller 9. In this case, the units that are illustrated are not necessarily to be understood as physically separate units, but merely represent a subdivision into sensory units, which can also be implemented, for example, in fewer or even in only a single physical unit.

Via an input/output facility (I/O interface) 28 of the magnetic resonance system 1, control commands can be passed to the magnetic resonance system, for example by a user, and/or results of the controller 9, such as image data, can be displayed.

A method described herein can also be in the form of a computer program that comprises commands that execute the described method on a controller 9. Likewise, a computer-readable storage medium can be present that comprises commands that, when executed by a controller 9 of a magnetic resonance system 1, prompt the latter to execute the described method.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first,” “second,” etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM);

magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for recording measurement data of an examination object by a magnetic resonance (MR) system using an echo planar recording technique segmented into at least two segments in a readout direction, the method comprising:
recording, using the MR system, the measurement data and associated navigator data in each of the at least two segments after a common radio-frequency (RF) excitation pulse in accordance with the used echo planar recording technique, which is segmented in the readout direction, for all of the at least two segments, wherein a sampling pattern, in accordance with which navigator data is recorded, is changed in at least one of the recordings of the measurement data of the at least two segments with their associated navigator data;
generating, by the MR system, reference data based on the navigator data recorded with a changed sampling pattern;
determining, by the MR system and based on reference data, further information;
improving, by the MR system and based on the further information, the recorded measurement data to generate improved measurement data; and
providing the improved measurement data in electronic form as a data file.

2. The method as claimed in claim 1, wherein the reference data is used as a reference for determining information for a correction method and/or for a supplementing method for supplementing measurement data that is not recorded.

3. The method as claimed in claim 1, wherein, when a sampling pattern is changed, an acceleration factor corresponding to the sampling pattern remains changed.

4. The method as claimed in claim 1, wherein the sampling patterns are changed such that the readout direction in which the navigator data is recorded reverses with the changed sampling pattern.

5. The method as claimed in claim 1, wherein the sampling patterns are changed such that the positions in the phase encoding direction at which the navigator data is recorded shift with the changed sampling pattern.

6. The method as claimed in claim 1, wherein the reference data is usable as a reference for a dual-polarity GeneRalized Autocalibrating Partially Parallel Acquisition (DP GRAPPA) technique, the sampling pattern, in accordance with which navigator data is recorded in the respective segments, being changed for segments such that, due to the changed sampling patterns, overall navigator data is recorded that completely samples k-space for each readout direction in accordance with Nyquist.

7. The method as claimed in claim 1, wherein the reference data is usable as a reference for a supplementing method adapted to supplement unrecorded measurement data, changed sampling patterns together resulting in a combined sampling pattern that completely samples a k-space center in accordance with Nyquist.

8. The method as claimed in claim 1, wherein the reference data is usable as a reference for a supplementing method adapted to supplement unrecorded measurement data, the changed sampling pattern corresponding to a sampling pattern used for recording reference measurement data for a parallel acceleration technique, which completely samples a k-space center in accordance with Nyquist.

9. The method as claimed in claim 8, wherein the parallel acceleration technique is an in-plane GeneRalized Autocalibrating Partially Parallel Acquisition (GRAPPA) technique.

10. The method as claimed in claim 1, wherein the navigator data is recorded in the segment of the echo planar recording technique, which is segmented into at least two segments in the readout direction and which comprises a k-space center.

11. The method as claimed in claim 1, wherein the measurement data and the associated navigator data is recorded after applying a diffusion preparation block.

12. The method as claimed in claim 1, wherein the echo planar recording technique comprises a Readout SEgmentation Of Long Variable Echo-trains (RESOLVE) recording technique that records navigator data for each of its segments.

13. A non-transitory computer-readable storage medium with an executable program stored thereon, that when executed, instructs a processor to perform the method of claim 1.

14. A magnetic resonance (MR) system comprising:
a MR scanner adapted to record measurement data of an examination object using an echo planar recording technique segmented into at least two segments in a readout direction; and
a controller adapted to:
controller the MR scanner to record the measurement data and associated navigator data in each of the at least two segments after a common radio-frequency (RF) excitation pulse in accordance with the used echo planar recording technique, which is segmented in the readout direction, for all of the at least two segments, wherein a sampling pattern, in accordance with which navigator data is recorded, is changed in at least one of the recordings of the measurement data of the at least two segments with their associated navigator data;
generate reference data based on the navigator data recorded with a changed sampling pattern;
determine further information based on reference data; and
improve, based on the further information, the recorded measurement data to generate improved measurement data.

15. The MR system as claimed in claim 14, wherein the MR scanner comprises: a magnetic unit, a gradient unit, and a high-frequency unit.

16. The MR system as claimed in claim 14, wherein the controller comprises a high-frequency transceiver controller adapted to control a high-frequency unit of the MR scanner, and a reference measurement data unit adapted to determine reference measurement data.
